(19) United States
(12) Patent Application Publication
(10) Pub. No.: US 2025/0105094 A1
(43) Pub. Date: Mar. 27, 2025

(54) INTEGRATED COOLING ASSEMBLIES FOR ADVANCED DEVICE PACKAGING AND METHODS OF MANUFACTURING THE SAME

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/373,588

(22) Filed: Sep. 27, 2023

(51) Int. Cl. H01L 23/433; H01L 23/00

(52) U.S. Cl. CPC H01L 23/4336; H01L 24/08; H01L 24/32; H01L 24/80; H01L 2224/08225; H01L 2224/32225; H01L 2224/80805; H01L 2924/351

(57) ABSTRACT

A device package comprising an integrated cooling assembly. The integrated cooling assembly comprising a semiconductor device and a manifold attached to the semiconductor device. The manifold comprises a top portion, a spacer extending downwardly from the top portion to a backside of the semiconductor device, and a vibrational membrane disposed between portions of the manifold. The top portion, the spacer, and the backside of the semiconductor device collectively define a coolant chamber volume therebetween.

### FIELD

The present disclosure relates to advanced packaging for microelectronic devices, and in particular, embedded cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communications and technology (ICT) ecosystem could exceed 20% of global electricity use by 2030, with direct electrical consumption by large-scale computing centers accounting for more than one-third of that energy usage. Cooling costs make up a significant portion of computing center energy requirements as even small increases in operating temperatures can negatively impact the performance of microprocessors, memory devices, and other electronic components.

Thermal dissipation in high-power density chips (semiconductor devices) is also a critical challenge as improvements in chip performance, e.g., through increased gate density and multi-core microprocessors, have resulted in increased power density and a corresponding increase in thermal flux that contributes to elevated chip temperatures. These elevated temperatures are undesirable as they can degrade the chip's operating performance, efficiency, and reliability. Cooling systems used to maintain the chip at a desired operating temperature typically remove heat using one or more heat dissipation devices, e.g., thermal spreaders, heat pipes, cold pipes, and heat sinks. Such cooling systems can suffer from reduced cooling efficiency due to the design and manufacture of system components.

Accordingly, there exists a need in the art for improved energy-efficient cooling systems and methods of manufacturing the same.

### SUMMARY

Embodiments herein provide integrated cooling assemblies embedded in advanced device packages. Advantageously, the integrated cooling assemblies increase convective heat transfer from a semiconductor device to a coolant fluid, which facilitates an increase in power density of advanced device packages.

One general aspect includes, a device package comprising an integrated cooling assembly. The integrated cooling assembly comprising a semiconductor device and a manifold attached to the semiconductor device. The manifold comprises a top portion and a spacer extending downwardly from the top portion to a backside of the semiconductor device. The manifold further comprises a vibrational membrane disposed between portions of the spacer. The top portion, the spacer, and the backside of the semiconductor device collectively define a coolant chamber volume therebetween.

In some embodiment, the vibrational membrane may comprise one or more openings.

In some embodiments, the vibrational membrane may comprise a first surface facing the backside of the semiconductor device and a second surface opposite the first surface. The one or more openings of the vibrational membrane may be conduits. Each conduit may be defined by a first opening in the first surface, a second opening in the second surface and a sidewall extending between the first and second openings.

In some embodiments, a cross-sectional width of the second opening may be greater than a cross-sectional width of the first opening

In some embodiments, the vibrational membrane may be configured to vibrate at a frequency from about 20 kHz to about 2 MHz.

In some embodiments, the vibrational membrane may comprise an actuator that generates sonic vibrations.

In some embodiments, the vibrational membrane may be configured to direct compressed streams of gas towards the backside of the semiconductor device.

Another general aspect includes a device package comprising an integrated cooling assembly. The integrated cooling comprising a semiconductor device and a manifold attached to the semiconductor device. The manifold comprises a top portion and a spacer extending downwardly from the top portion to a bottom portion of the manifold. The manifold further comprises a vibrational membrane disposed between portions of the spacer. The top portion, the spacer, and the bottom portion collectively define a coolant chamber volume therebetween.

Another general aspect includes a method of manufacturing a device package. The method comprises directly bonding a first substrate comprising the manifold of any of the previous aspects to a second substrate comprising a semiconductor device. The method further comprises singulating an integrated cooling assembly comprising the semiconductor device and the manifold from the bonded first and second substrates.

### BRIEF DESCRIPTION OF THE DRAWINGS

The above and other objects and advantages of the disclosure will be apparent upon consideration of the following detailed description, taken in conjunction with the accompanying drawings, in which:

FIG. 1A is a schematic plan view of an example of a system panel, in accordance with embodiments of the disclosure;

FIG. 1B is a schematic partial sectional side view of a device package mounted on a PCB, in accordance with embodiments of the disclosure;

FIG. 2A is a schematic sectional view of an example device package, in accordance with embodiments of the present disclosure, that may be used with the system panel;

FIG. 2B is a schematic view of a vibrational membrane, according to some embodiments, that may be used with the device package;

FIG. 2C is a schematic isometric view of vibrational membrane openings and helicoidal ribs, according to some embodiments, that may be used with example integrated cooling assemblies;

FIG. 3 is a schematic sectional view of example spacers, in accordance with embodiments of the present disclosure, that may be used with the integrated cooling assemblies;

FIG. 4A is a schematic sectional view of another example device package, in accordance with embodiments of the present disclosure, that may be used with the system panel;

FIG. 4B is a schematic sectional view of another example device package, in accordance with embodiments of the present disclosure, that may be used with the system panel;

FIG. 5 is a schematic sectional view of another example device package, in accordance with embodiments of the present disclosure, that may be used with the system panel;

FIG. 6 shows a method that can be used to manufacture the integrated cooling assemblies described herein.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed. The term substrate also includes “semiconductor substrates” that provide a supporting material upon which elements of a semiconductor device are fabricated or attached, and any material layers, features, and/or electronic devices formed thereon, therein, or therethrough.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” are also used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,”, “top”, “bottom”” and the like are generally made with reference to the X, Y, and Z directions set forth by X, Y and Z axis in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements. Furthermore, the terms “horizontal” and “vertical” are generally made with reference to the X and Z directions set forth in the drawings, respectively.

Various embodiments disclosed herein include bonded structures in which two or more elements are directly bonded to one another without an intervening adhesive (referred to herein as “direct bonding”, or “directly bonded”). In some embodiments, direct bonding includes the bonding of a single material on the first of the two or more element and a single material on a second one of the two more elements, where the single materials on the different elements may or may not be the same. Direct bonding can also include bonding of multiple materials on one element to multiple materials on the other element (e.g., hybrid bonding). As used herein, the term “hybrid bonding” refers to a species of direct bonding in which you have both i) nonconductive features directly bond to nonconductive features, and ii) conductive features directly bond to conductive features.

Unless otherwise noted, the terms “cooling assembly” and “integrated cooling assembly” generally refers to a semiconductor device and a manifold attached to the semiconductor device. Typically, the manifold is formed with recessed surfaces that define a fluid cavity (e.g., a coolant chamber volume) between the manifold and the semiconductor device. The fluid cavity may alternatively be referred to as a cooling chamber volume. The manifold may comprise a polymer material. The manifold may alternatively be referred to as a cold plate. The manifold may be attached to the semiconductor device by use of a compliant adhesive layer or by direct dielectric or hybrid bonding. For example, the manifold may include material layers and or metal features which facilitate direct dielectric or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants. Example liquids include: water, deionized water, glycol, a mixture of water and glycol (e.g. ethylene glycol and water (EGW) and propylene glycol and water (PGW), dielectric fluids (e.g. fluorocarbons, polyalphaolefin (PAO), etc.). Example gases include atmospheric air and/or one or more inert gases such as nitrogen. Atmospheric air may be taken to mean the mixture of different gases in Earth's atmosphere made up of approximately 78% nitrogen and 21% oxygen. In some embodiments, the coolant fluids may contain additives to enhance the conductivity of the cooling fluid within the integrated cooling assemblies. The additives may comprise for example, nano-particles of carbon nanotube, nano-particles of graphene, nano-particles of metal oxides. The concentration of these nano-particles may be less than 1%, less than 0.2% and still less than 0.05%. The cooling fluids may also contain small amount of glycol or glycols (e.g. propylene glycol, ethylene glycol etc.) to reduce frictional shear stress and drag coefficient in the cooling fluid within the integrated cooling assembly.

As described below, coolant fluid flowing through a manifold may be used to control the temperature of semiconductor devices. The fluid flowing across the surface of the semiconductor device absorbs heat and conducts heat away from the device.

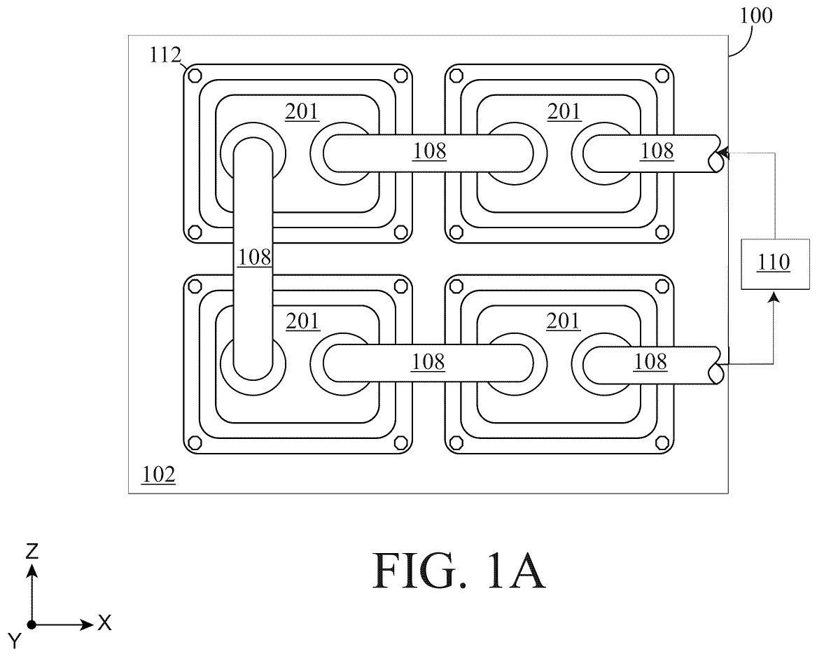

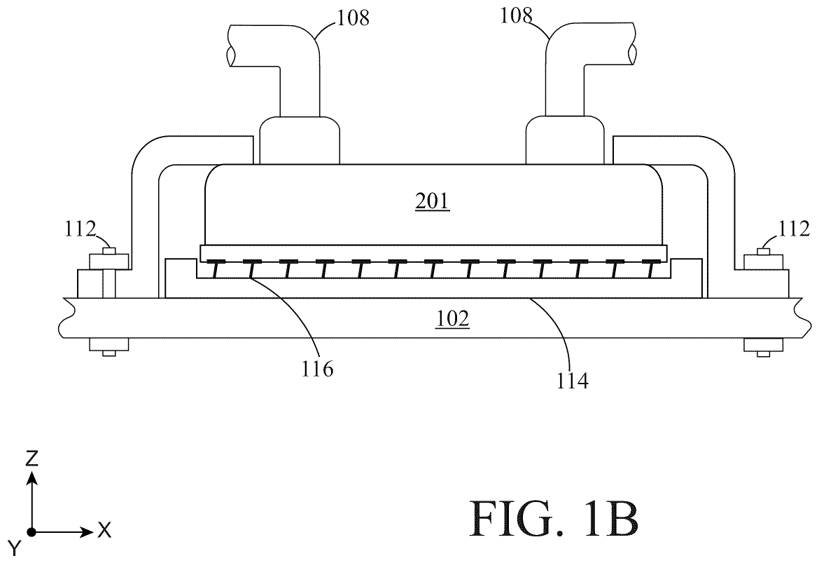

FIG. 1A is a schematic plan view of an example of a system panel 100, in accordance with embodiments of the disclosure. Generally, the system panel 100 includes a printed circuit board, here PCB 102, a plurality of device packages 201 mounted to the PCB 102, and a plurality of coolant delivery lines 108 fluidly coupling each of the device packages 201 to a coolant source 110. It is contemplated that coolant may be delivered to each of the device packages 201 in any desired fluid phase, e.g., liquid, vapor, gas, or combinations thereof and may flow out from the device package 201 in the same phase or a different phase. In some embodiments the coolant is delivered to the device package 201 and returned therefrom as a liquid and the coolant source 110 may comprise a heat exchanger or chiller to maintain the coolant at a desired temperature. In other embodiments, the coolant may be delivered to the device packages 201 and returned therefrom as a gas, and the coolant source 110 may comprise a heat exchanger or chiller to maintain the coolant at a desired temperature. In other embodiments, the coolant may be delivered to the device packages 201 as a liquid, vaporized to a liquid within the device package, and returned to the coolant source 110 as a vapor. In those embodiments, the device packages 201 may be fluidly coupled to the coolant source 110 in parallel and the coolant source 110 may include or further include a compressor (not shown) for condensing the received vapor to a liquid form.

FIG. 1B is a schematic partial sectional side view of a portion of the system panel 100 of FIG. 1A. As shown, each device package 201 is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame and a plurality of fasteners 112, e.g., compression screws, collectively configured to exert a relatively uniform downward force on the upward facing edges of the device package 201. The uniform downward force ensures proper pin contact between the device package 201 and the socket 114.

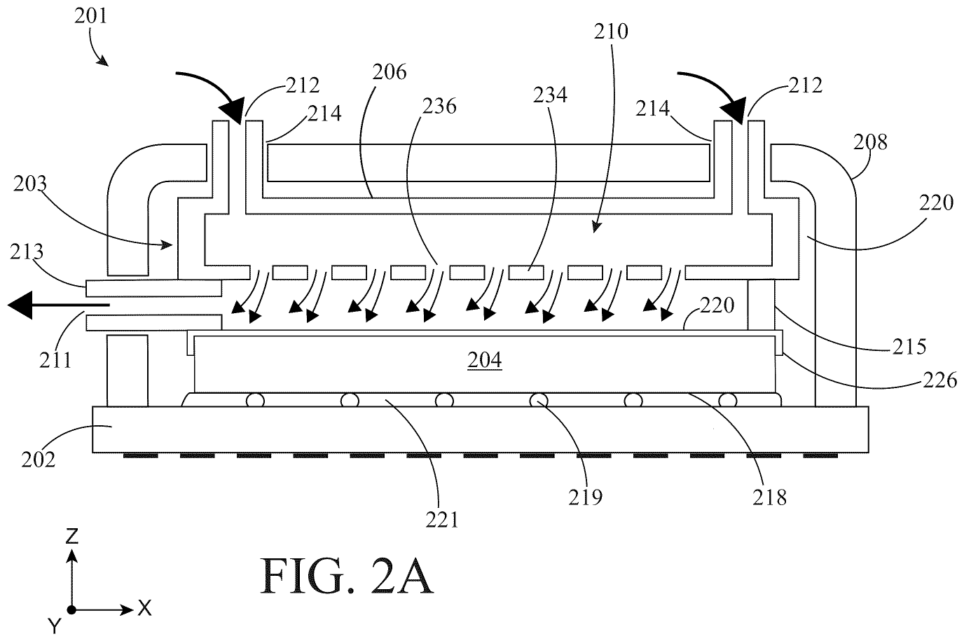

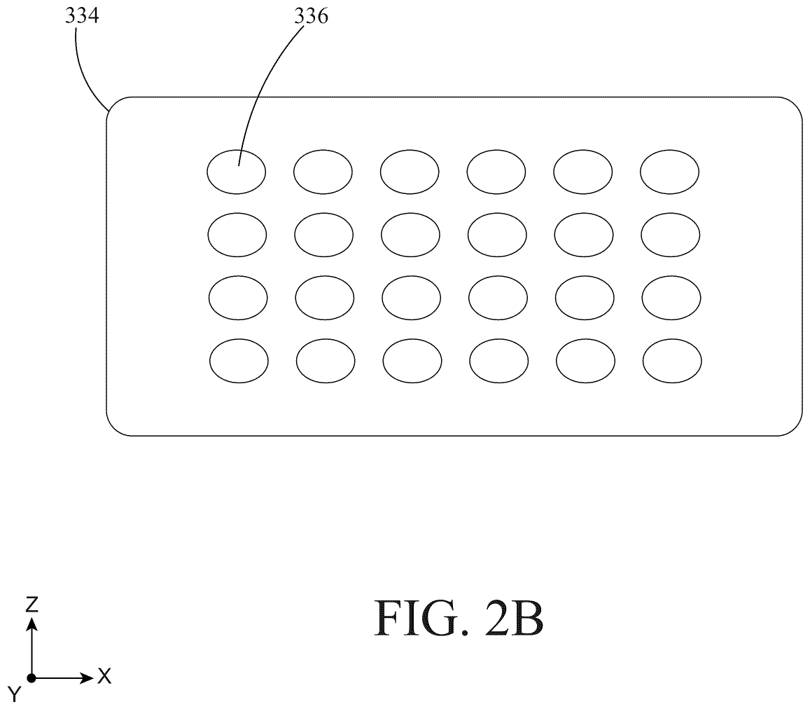

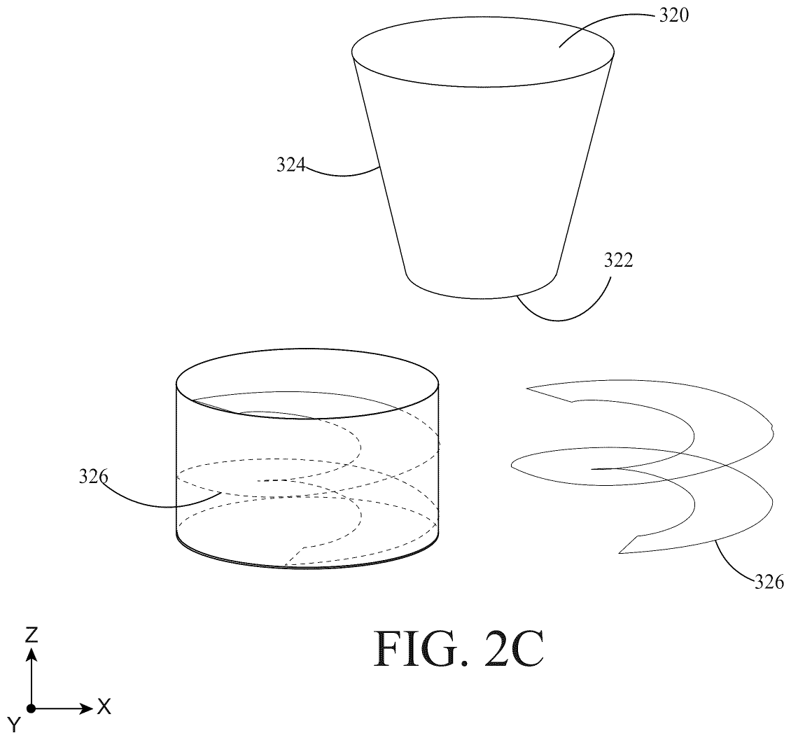

FIG. 2A is a schematic sectional view of an example device package 201, in accordance with embodiments of the present disclosure. Generally, the device package 201 includes a package substrate 202, an integrated cooling assembly 203 disposed on the package substrate 202, and a package cover 208 disposed on a peripheral portion of the package substrate 202. The package cover 208 extends over the integrated cooling assembly 203 so that the integrated cooling assembly 203 is disposed between the package substrate 202 and the package cover 208. Here, portions of the manifold 206 extend through openings 214, 213 in the package cover 208 to facilitate attachment of coolant delivery lines 108. In some embodiments, the coolant delivery lines may be attached directly to the package cover. The device package 201 may further include a sealing material layer (not shown) that forms a coolant impermeable barrier between the package cover 208 to the integrated cooling assembly 203. Coolant is delivered to the integrated cooling assembly 203 via inlet openings 212 in the manifold 206 formed through the package cover 208 and, optionally, corresponding openings formed through the sealing material layer. Coolant exits the integrated cooling assembly 203 via an outlet opening 211 formed through the package cover 208 and, optionally, a corresponding opening formed through the sealing material layer.

In FIG. 2A, the inlet openings 212 are formed in a top surface of the manifold 206 and the outlet opening 211 is formed in an orthogonal side surface of the manifold 206 (e.g., as part of a spacer 215, as discussed in more detail below). In other embodiments, the outlet opening 211 may instead be formed on the top surface of the manifold 206, for example in place of one of the inlet openings 212. It will be understood that the inlet openings 212 and the outlet opening 211 are shown in a section view. The openings 212, 211 may have any cross-sectional shape that allows fluid to flow therethrough. For example, the openings 212, 211 may have rectangular, square, hexagonal or circular cross-sections. It will also be understood that a portion the outlet opening 211 adjacent to the semiconductor device 204 may be formed (at least in part) by a portion of the backside 220 of the semiconductor device 204. That is, the outlet opening 211 may comprise two opposite sidewalls extending between an upper wall of the outlet opening 211 and the backside 220 of the semiconductor device 204.

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couple the integrated cooling assembly 203 to a system panel, such as the PCB 102.

The integrated cooling assembly 203 typically includes a semiconductor device, here device 204, and a manifold 206 bonded to the semiconductor device 204. Here, the semiconductor device 204 includes an active side 218 that includes device components, e.g., transistors, resistors, and capacitors, formed thereon or therein, and a non-active side, here the device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. The manifold 206 may be disposed on the package substrate 202 with the semiconductor device 204 attached to the package substrate 202. For example, the semiconductor device 204 may be disposed between the manifold 206 and the package substrate 202.

In some embodiments, the backside 220 of the semiconductor device 204 comprises a corrosion protective layer 226. The corrosion protective layer 226 may be a continuous layer disposed across the entire backside 220 of the semiconductor device 204, such that the manifold 206 is attached thereto. Beneficially, the corrosion protective layer 226 provides a corrosion resistant barrier layer, thus preventing undesired corrosion of the semiconductor device 204 (e.g., the semiconductor substrate material which might otherwise be in direct contact with fluid flowing through a coolant chamber volume).

Here, the device package 201 comprises an integrated cooling assembly 203 comprising a semiconductor device 204 and a manifold 206 attached to the semiconductor device 204. The manifold 206 comprises a top portion and a spacer 215 extending downwardly from the top portion to the backside 220 of the semiconductor device 204. The top portion of the manifold 206 comprises a first side facing towards the semiconductor device 204 and a second side opposite the first side. The second side faces the package cover 208 (e.g., the second side is external to a coolant chamber volume 210 and faces away from the semiconductor device 204).

The manifold 206 may be formed of any suitable material that has sufficient structural strength to withstand the desired pressures of the coolant flowed into the chamber volume. For example, the manifold 206 may be formed of a material selected from a group comprising polymers, metals, ceramics, or composites thereof. In some embodiments, the manifold 206 may formed of stainless steel (e.g., from a stainless steel metal sheet) or a sapphire plate. In some embodiments, the manifold 206 may be formed of a material having a substantially different coefficient of thermal expansion (CTE) from the semiconductor device, e.g., a CTE mismatched material. In such embodiments, the manifold 206 may be attached to the semiconductor device 204 by a compliant adhesive layer 328 or a molding material that absorbs the difference in expansion between the manifold and the semiconductor device across repeated thermal cycles.

The spacer 215 may be a layer of adhesive (e.g. molding material, die attach material, etc.) formed around a perimeter of the semiconductor device 204 in order to increase the distance between the top potion of the manifold 206 and the semiconductor device 204, which increases the volume of the coolant chamber volume 210. The spacer 215 (i.e., molding material) forms lower coolant chamber walls, the manifold 206 forms a coolant chamber cap and upper coolant chamber walls, and the backside 220 of the semiconductor device 204 forms a bottom of the coolant chamber volume 210 and is in thermal contact with fluid flowing therethrough. The inlet openings 212 and the outlet opening 211 of the manifold 206 may be in fluid communication with the coolant chamber volume 210. Furthermore, the inlet openings 212 and the outlet opening 211 of the manifold 206 may be in fluid communication with the inlet and outlet openings of the package cover 208. Therefore, the inlet and outlet openings of the package cover 208 may also be in fluid communication with the coolant chamber volume 210.

As shown, the outlet opening 211 may be formed from the spacer 215 itself. That is, a portion of the spacer 215 may extend through the package cover 208 to form the outlet opening 211 described above. In other embodiments, the outlet opening 211 may be attached to an opening in the sidewall in order for fluid to exit from the coolant chamber volume 210.

The manifold 206 further comprises a vibrational membrane 234 disposed between portions of the manifold 206. The top portion of the manifold 206, the spacer 215, and the backside 220 of the semiconductor device 204 collectively define the coolant chamber volume 210 therebetween.

The portions of the manifold 206 between which the vibrational membrane 234 extends may be positioned inside the coolant chamber volume 210 such that the vibrational membrane 234 is disposed inside the coolant chamber volume 210. For example, where the spacer 215 is formed around a perimeter of the semiconductor device 204, the spacer 215 may comprise sidewalls (e.g., four sidewalls in embodiments where the semiconductor device is square or rectangular). The vibrational membrane 234 may extend between each sidewall of the spacer 215 such that the vibrational membrane 234 extends across, and is spaced away from, the backside 220 of the semiconductor device 204. In other embodiments, as illustrated in FIG. 2A, the vibrational membrane 234 may extend between upper sidewalls (e.g., portions) of the manifold 206 above the spacer 215 such that the vibrational membrane 234 extends across, and is spaced relatively further away from, the backside 220 of the semiconductor device 204. As shown, the vibrational membrane 234 has a substantially horizontal orientation, such that the vibrational membrane 234 extends the X-axis direction.

Here, the vibrational membrane 234 is disposed inside the coolant chamber volume 210 between the top portion of the manifold and the semiconductor device 204 and is spaced apart from the top portion of the manifold 206. Spaced apart is taken to mean that upper sidewalls of the manifold 206 extend between the top portion and the vibrational membrane such that a fluid cavity is formed therebetween. Thus, the vibrational membrane 234 defines an upper fluid volume with the top portion (e.g., upper portion) of the manifold 206 and a lower fluid volume with the semiconductor device 204. That is, the upper fluid volume is disposed above the vibrational membrane 234 and the lower fluid volume is disposed below the vibrational membrane 234. The distance between the semiconductor device 204 and the vibrational membrane 234 may be adjusted compared to the distance between the top portion of the manifold 206 and the vibrational membrane 234, by moving the position of the vibrational membrane 234 up or down within the coolant chamber volume 210, to adjust the relative volumes of the upper fluid volume and the lower fluid volume. The upper fluid volume may alternatively be referred to as a fluid cavity.

In some embodiments, the manifold 206 may comprise a vibration damping material (not shown). The vibration damping material may be, for example, a vibration damping layer disposed on portions of an external surface of the manifold 206 in order to mitigate the transfer of vibrations generated by the vibrational membrane 234 to the semiconductor device 204. It will be understood that the vibration material may be provided on other portions of the manifold, for example in the coolant chamber volume 210. In some embodiments, a low modulus material (e.g. a layer of die attach material) may act as a vibration damping layer.

Here, the lower fluid volume is in fluid communication with the upper fluid volume through a one or more openings 236 in the vibrational membrane 234, discussed in more detail below with reference to FIG. 2B. The openings 236 provide a means for fluid to flow between the upper fluid volume and the lower fluid volume. An example flow path of fluid through the upper fluid volume and the lower fluid volume may be as follows:
1. fluid enters the upper fluid volume through the inlet opening 212;
2. fluid flows from the upper fluid volume to the lower fluid volume through the openings 236 of the vibrational membrane 234;
3. fluid flows across the backside 220 of the semiconductor device 204 and absorbs heat generated by the semiconductor device 204;
4. the fluid exits the coolant chamber volume 210 through outlet opening 211.

In some embodiments, the vibrational membrane 234 may comprise an actuator and/or a transducer that converts an electrical input signal, received from control circuitry, into linear physical motion thus generating sonic vibrations. The vibrational membrane 234 may vibrate at a frequency from about 20 kilohertz (kHz) to about 2 megahertz (MHz). This frequency range may be referred to as ultrasonic frequency. In embodiments where the fluid is a gas (e.g., atmospheric air or nitrogen, as discussed above), as gas enters the coolant chamber volume 210 via the inlet openings 212, the gas is directed towards the backside 220 of the semiconductor device 204 via the vibrational membrane 234. As the gas passes through the openings 236 of the vibrational membrane 234, the gas becomes compressed due to the oscillating vibrational membrane 234 and provides jet cooling of the semiconductor device 204. That is, the compressed gas impinges directly on the backside 220 of the semiconductor device 204 to provide effective cooling thereof by means of pulsating jet streams of gas. It will be understood that liquid may be used instead of gas in certain embodiments.

The spacer 215 of the manifold 206 may direct the compressed gas towards the backside 220 of the semiconductor device 204 through the coolant chamber volume 210. Beneficially, the spacer 215 focusses the compressed gas towards the backside 220 of the semiconductor device 204 for effective and efficient cooling thereof.

In some embodiments, the vibrational membrane 234 may be powered from the semiconductor device 204. In other embodiments, the vibrational membrane 234 may be powered by direct wiring (or any form of electrical connection) connected to an external interface at the package substrate. The vibrational membrane may be controlled either by a connection to control circuitry located on the semiconductor device or by a connection to external control circuitry.

Example transducers which may be used to vibrate the vibrational membrane 234 include: magnetostrictive transducers and piezoelectric transducers. Furthermore, such transducers may be implemented as microelectromechanical system (MEMS) devices.

Beneficially, the pulsating jets of compressed gas increase convective heat transfer from the semiconductor device 204 to the fluid by thinning the stagnant fluid boundary layer adjacent to the backside 220 of the semiconductor device 204. Furthermore, turbulence introduced by the vibrational membrane 234 reduces the occurrence of hot spots in the semiconductor device 204 by encouraging movement of the gas across the entire backside 220 of the semiconductor device 204. The improved heat transfer effects provided by the vibrational membrane 234 facilitate an increased power density of the device package 201.

FIG. 2B is a schematic view of the vibrational membrane 334, according to some embodiments, that may be used with the device package 201. The vibrational membrane 334 may comprise a first surface facing the backside 220 of the semiconductor device 204 and a second surface opposite the first surface (e.g., the second surface facing an upper portion of the manifold 206 above the vibrational membrane 334 in the X-axis direction).

A plurality of openings 336 may be arranged in rows and/or columns of rectangular, circular, oval, hexagonal or any other shaped openings. Typically, the sharp corners in these holes are to be avoided for high flow applications. Using strong membrane material or designing a robust membrane may alleviate the reliability issue. In particular, the vibrational membrane 334 of FIG. 2B is illustrated as comprising four rows of rectangular openings across six columns. It will be understood that plural vibrational membranes 334 may be stacked inside the coolant chamber volume 210 in order to provide additional control and compression of fluid as it passes through each stacked vibrational membrane 334.

FIG. 2C is a schematic isometric view of the vibrational membrane openings 336, according to some embodiments, that may be used with the device package 201. Here, the one or more openings 336 of the vibrational membrane 334 may form conduits, whereby each conduit is defined by a first opening 322 in the first surface, a second opening 320 in the second surface, and a sidewall 324 extending between the first and second openings 320, 322. In the embodiments of FIG. 2C, the conduits have a circular cross-section. The conduit may have a length equal to or greater than a thickness of the vibrational membrane 234 in the Z-axis direction.

In some embodiments, the sidewalls 324 of the plurality of openings 236 (e.g., conduits) may be funnel shaped (e.g., conical) such that a cross-section of an upper opening facing the upper portion of the manifold 206 is greater than a cross-section of a lower opening facing the semiconductor device 204. That is, a cross-sectional width of the second opening 320 in the X-axis direction may be greater than a cross-sectional width of the first opening 322 in the X-axis direction. The funnel shaped sidewalls 324 accelerate the flow of fluid as the fluid flows through the openings. The accelerated flow focuses compressed fluid streams towards certain areas of the backside 220 of the semiconductor device 204.

The sidewalls may comprise helicoid ribs 326, as illustrated in FIG. 2C. The helicoid ribs 326 generate a vortex in fluid flowing from the upper fluid volume (e.g., the fluid cavity) to the lower fluid volume. That is, as fluid flows through the plurality of openings 236, the helicoid ribs 326 guide the fluid in a downward circular motion thus generating a vortex in the fluid. The fluid vortex induces massive stirring on the backside 220 of the semiconductor device 204, thus thinning the fluid boundary layer and enhancing heat transfer from the semiconductor device 204 to the fluid.

Overall performance of the device package 201 is improved due to the enhanced cooling properties provided by the vibrational membrane 234 optionally in combination with the helicoidal ribs and/or funnel shaped sidewalls. For example, compressed jet streams of fluid generated by the vibrational membrane 234 may be transferred towards the backside 220 of the semiconductor device 204 in the form of a vortex, induced by helicoidal ribs of the openings 236. Furthermore, the pressure at which the compressed fluid is projected towards the backside 220 of the semiconductor device 204 may be increased by the funnel shaped sidewalls 324, which increase the rate of flow at which fluid passes through the openings 236 and across the backside 220 of the semiconductor device 204. The vibrational membrane 234 may be attached to the manifold 206 by any suitable method, e.g., by use of fasteners, an adhesive, or through direct bonding of the surfaces without the use of an intervening adhesive.

In some embodiments, the vibrational membrane 234 may be formed from silicon, polysilicon, doped polysilicon, polymers, lithium niobate, lithium tantalate, quartz, acoustic membrane metamaterials, for example.

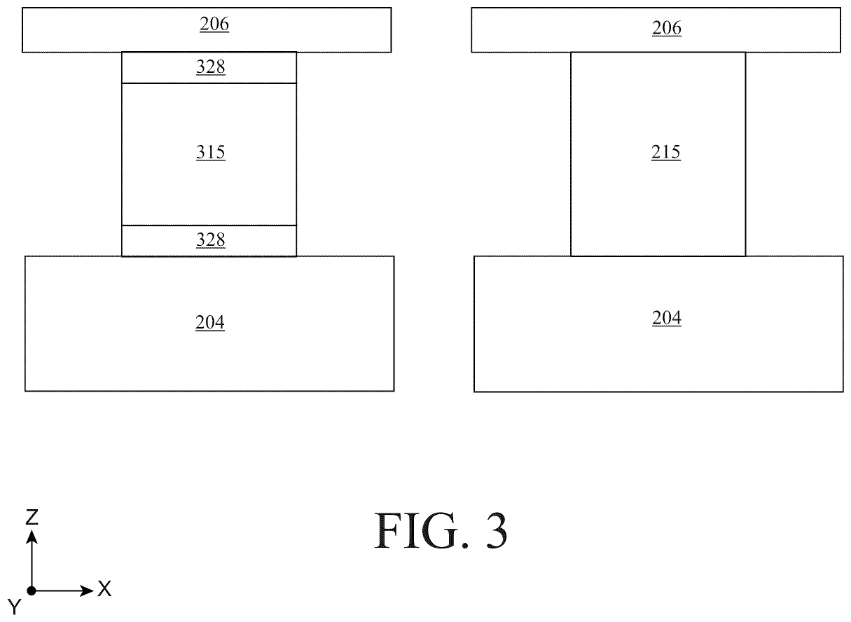

FIG. 3 is a schematic sectional view of example spacers, in accordance with embodiments of the present disclosure. As illustrated by the spacer 315 on the left hand side of FIG. 3, the spacer 315 may be thermally coupled between the top portion of the manifold 206 and the semiconductor device 204 using a compliant adhesive layer 328, such as a thermally conductive paste, grease, adhesive material, or other thermally conductive material, such as a fusible metal alloy and the like, e.g., solder, or combinations thereof. A compliant adhesive layer 328 may be disposed directly between the manifold 206 and an upper surface of the spacer 315 and directly between the semiconductor device 204 and a lower surface of the spacer 315.

As illustrated by the spacer 215 on the right hand side of FIG. 3, the spacer 215 may be attached between the top portion of the manifold 206 and the semiconductor device 204 without the use of an intervening adhesive material. Thus, an upper surface of the spacer 215 may be directly bonded to the top portion of the manifold 206 such that the spacer 215 and the top portion of the manifold 206 are in direct contact. Further, a lower surface of the spacer 215 may be directly bonded to the semiconductor device 204 such that the spacer 215 and the semiconductor device 204 are in direct contact.

In some embodiments, the spacer 215 is attached between the top portion of the manifold 206 and the semiconductor device 204 using a direct dielectric bonding process. In other embodiments, the spacer 215 is attached between the top surface of the manifold 206 and the semiconductor device 204 using a hybrid of direct dielectric bonds and direct metal bonds formed therebetween. For example, in some embodiments, one or both of the top portion and the top portion-facing side of the spacer 215 (e.g., the upper surface of the spacer 215) comprise a dielectric material layer, e.g., a first dielectric material layer and a second dielectric material layer respectively and the spacer 215 is directly bonded to the top portion through bonds formed between the dielectric material layers. Similarly, one or both of the semiconductor device 204 and the device-facing side of the spacer 215 (e.g., the lower surface of the spacer 215) comprise a dielectric material layer, e.g., a first dielectric material layer and a second dielectric material layer respectively and the spacer 215 is directly bonded to the semiconductor device 204 through bonds formed between the dielectric material layers.

In some embodiments, the spacer 215 is attached between the top portion of the manifold 206 and the semiconductor device 204 using a hybrid bonding technique, where bonds are formed between the dielectric material layers and between metal features, such as between first metal pads and second metal pads, disposed in the dielectric material layers.

Suitable dielectrics that may be used as the dielectric material layers include silicon oxides, silicon nitrides, silicon oxynitrides, silicon carbon nitrides, metal-oxides, metal-nitrides, silicon carbide, silicon oxycarbides, silicon oxycarbonitride, silicon carbonitride, diamond-like carbon (DLC), or combinations thereof. In some embodiments, one or both of the dielectric material layers are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, 100 nm or more, or 100 nm or more. In some embodiments, the one or both of the layers are deposited to a thickness of 300 nm or less, such as 100 nm or less, 100 nm or less, or 50 nm or less.

In some embodiments, the spacer 215 is attached between the top portion of the manifold 206 and the semiconductor device 204 using an eutectic bonding process, where metal alloys are used as an intermediate layer to form a continuous bond. Layers of metal alloy are heated until atomic bonds is formed between the spacer 215 and the top portion of the manifold 206 and between the spacer 215 and the semiconductor device 204. Example metal alloys used for eutectic bonding include solder/tin, nickel-copper-tin, gold-tin, gold-germanium, copper-silver, and gold-silicon.

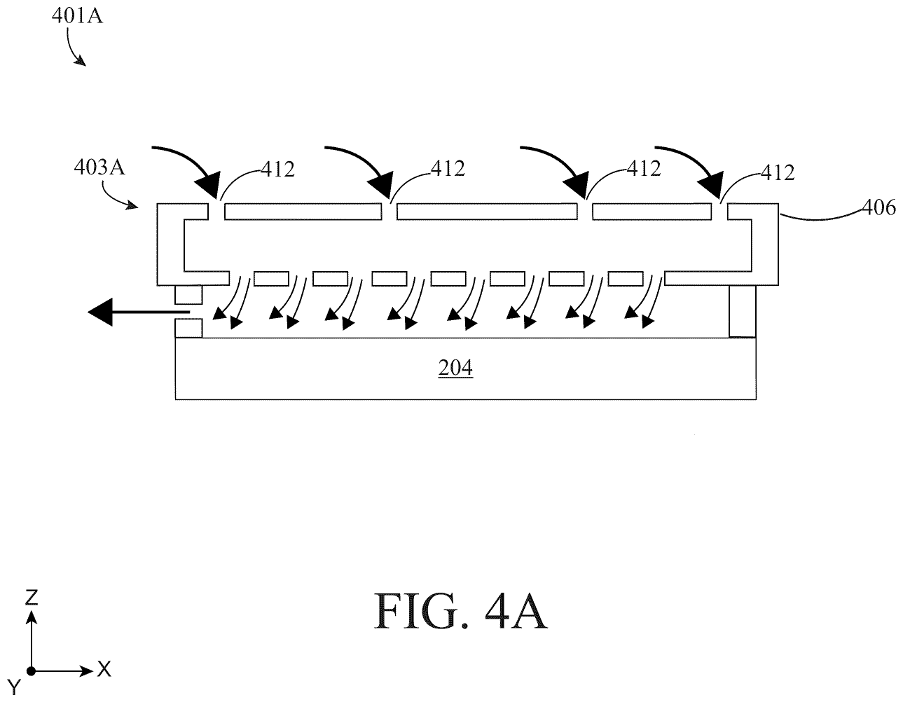

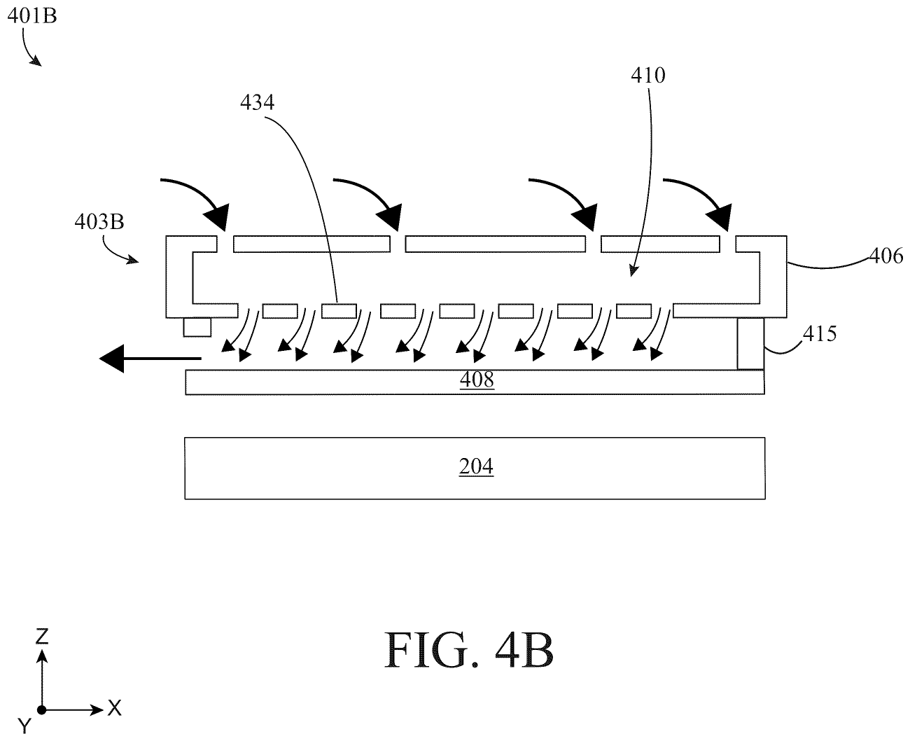

FIG. 4A is a is a schematic sectional view of device package 401A, according to another embodiment, that may be used with the system panel 100. Here, the device package 401A comprises an integrated cooling assembly 403A comprising a manifold 406 attached to a semiconductor device 204, such as described above in relation to FIG. 2A. The manifold 406 comprises four inlet opening 412 through which coolant may flow. It will be understood that more than four inlet openings 412 may be provided.

FIG. 4B is a is a schematic sectional view of device package 401B, according to another embodiment, that may be used with the system panel 100. Here, the device package 401A comprises an integrated cooling assembly 403A including a manifold 406 comprising a top portion and a bottom potion 408. A spacer 415 extending downwardly from the top portion to the bottom portion 408 of the manifold 406 and a vibrational membrane 434 is disposed between portions of the manifold 406, such as described above in relation to FIG. 2A. In particular, the vibrational membrane 434 is disposed between the top portion and the bottom portion 408. The top portion, the spacer 415, and the bottom portion 408 collectively define a coolant chamber volume 410 therebetween. Here, the bottom portion 408 of the manifold 406 is attached to the semiconductor device by various bonding techniques, such as discussed above in relation to FIG. 2A.

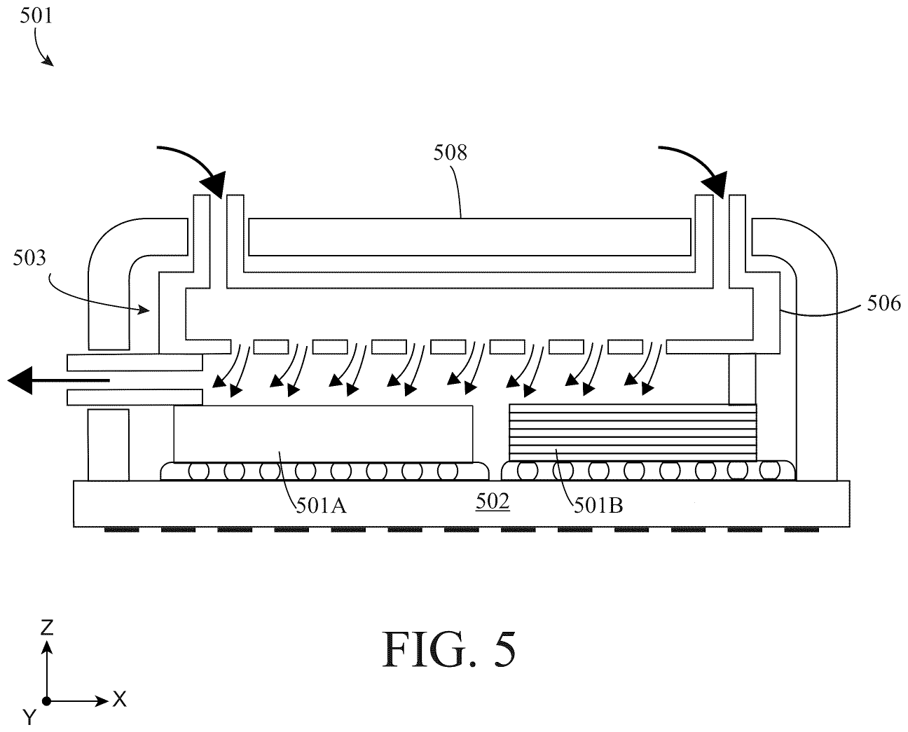

FIG. 5 is a schematic side sectional view of an example of a multi-component device package 501 that includes a manifold 506 directly bonded to the backside surfaces of two or more devices 501A, 501B. As shown, the device package 501 includes a package substrate 502, an integrated cooling assembly 503 and a package cover 508. The integrated cooling assembly 503 may include a plurality of devices 501A (one shown) which may be singulated and/or disposed in a vertical device stack 501B (one shown). The manifold 506 may be attached to each of the devices 501A and device stack 501B, e.g., by the direct bonding methods described herein or other method including flip chip bonding, etc. In some embodiments, the device 501A may comprise a processor and the device stack 501B may comprise a plurality of memory devices. Here, the device 501A and the device stack 501B are disposed in a side-by-side arrangement on the package substrate 502 and are in electrical communication with one another through conductive elements formed in, on, or through the package substrate 502. Here, the manifold 506 is sized to provide a bonding surface for attachment to both the device 501A and the device stack 501B but may otherwise be the same or substantially similar to other manifolds described herein.

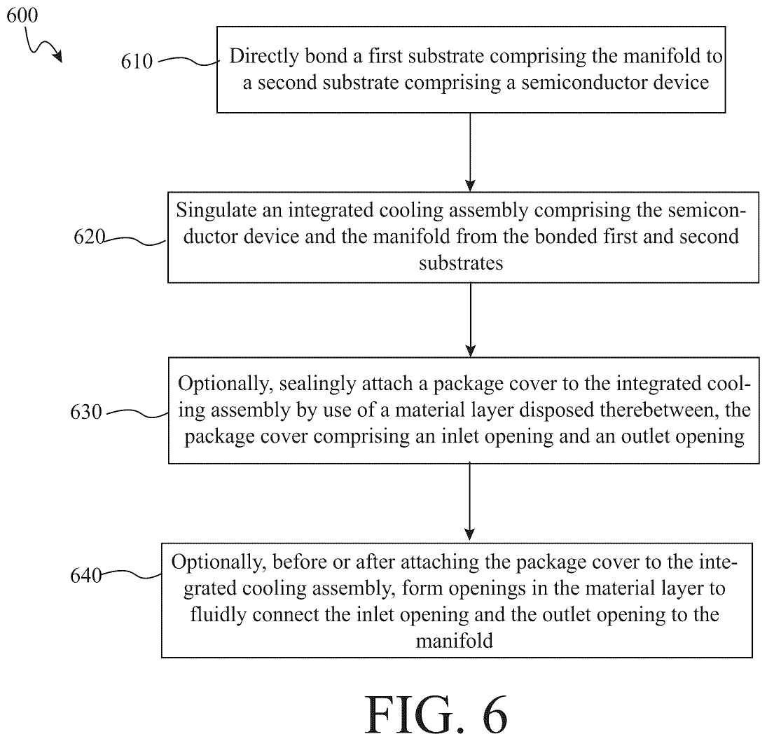

FIG. 6 is a flow diagram setting forth a method 600 of forming an integrated cooling assembly, according to embodiments of the disclosure.

At block 610, the method 600 includes directly bonding a first substrate (e.g., a monocrystalline silicon wafer) comprising the manifold 206, 406, 506 to a second substrate (e.g., a monocrystalline silicon wafer) comprising a semiconductor device 204, 501. For example, the first and second substrates may be etched using a patterned mask layer formed on surfaces of the respective substrates. The anisotropic etch process uses inherently differing etch rates for the silicon material which is exposed to an anisotropic etchant when the patterned mask layer is formed. It will be understood that, in some embodiments, the first substrate and/or the second substrate may be a semiconductor device (e.g., a die), such that block 610 may include direct die-to-die bonding and direct wafer-to-die bonding, in addition to wafer-to-wafer bonding.

In some embodiments, the etching process is controlled to where the etch rates of the exposed silicon material have a ratio between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN4OH), hydrazine (N2H4), or tetra methyl ammonium hydroxide (TMAH). The actual differing etch rates depend on the concentration of the etchant in the aqueous solution, the temperature of the aqueous solution, and a concentration of the dopant in the substrates (if any).

Typically, the mask layer is formed of a material which is selective to anisotropic etch compared to the underlying monocrystalline silicon substrate. Examples of suitable mask materials include silicon oxide (SixOy) or silicon nitride (SixNy). In some embodiments, the mask layer has a thickness of about 100 nm or less, such as about 50 nm or less, or about 30 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon germanium, germanium, group III-V semiconductor materials, group II-VI semiconductor materials, or combinations thereof. For example, in some embodiments, the second substrate may include a monocrystalline wafer, such as a silicon wafer, a plurality of device components formed in or on the silicon wafer, and a plurality of interconnect layers formed over the plurality of device components. In other embodiments, the substrate may comprise a reconstituted substrate, e.g., a substrate formed from a plurality of singulated devices embedded in a support material.

The bulk material of the second substrate may be thinned after the devices are formed using one or more backgrind, etching, and polishing operations that remove material from the backside. Thinning the second substrate may include using a combination of grinding and etching processes to reduce the thickness (in the Z-direction) to about 450 um or less, such as about 201 um or less, or about 150 um or less. After thinning, the backside may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process.

In some embodiments, an active side 218 is temporarily bonded to a carrier substrate (not shown) before or after the thinning process. When used, the carrier substrate provides support for the thinning operation and/or for the thinned material to facilitate substrate handling during one or more of the subsequent manufacturing operations described herein.

Here, the method 600 may include forming dielectric layers on the manifold 206 and the second substrate, and directly bonding includes forming dielectric bonds between a first dielectric material layer of the manifold 206 and a second dielectric material layer of the second substrate.

Generally, directly bonding the surfaces (of the dielectric material layers) includes preparing, aligning, and contacting the surfaces. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the substrates using a chemical mechanical polishing (CMP) process. Activating and terminating the surfaces with a desired species may include exposing the surfaces to radical species formed in a plasma.

In some embodiments, the plasma is formed using a nitrogen-containing gas, e.g., N₂, and the terminating species includes nitrogen and hydrogen. In some embodiments, the surfaces may be activated using a wet cleaning process, e.g., by exposing the surfaces to an aqueous ammonia solution. In some embodiments, the dielectric bonds may be formed using a dielectric material layer deposited on only one of the substrates but not on both. In those embodiments, the direct dielectric bonds may be formed by contacting the deposited dielectric material layer of one substrate directly with a bulk material surface of the other substrate.

Directly forming direct dielectric bonds between the substrates includes bringing the prepared and aligned surfaces into direct contact at a temperature less than 150° C., such as less than 100° C., for example, less than 30° C., or about room temperature, e.g., between 20° C. and 30° C. Without intending to be bound by theory, it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C. for a duration of about 5 minutes or more, such as about 15 minutes. Typically, the bonds will strengthen over time even without the application of heat. Thus in some embodiments, the method does not include heating the substrates.

After the dielectric bonds are formed, the substrates may be heated to a temperature of 150° C. or more and maintained at the elevated temperature for a duration of about 1 hour or more, such as between 8 and 24 hours, to form direct metallurgical bonds between the metal features. Suitable direct dielectric and hybrid bonding technologies that may be used to perform aspects of the methods described herein include ZiBond® and DBI® , each of which are commercially available from Adeia Holding Corp., San Jose, CA, USA.

At block 620, the method 600 includes singulating an integrated cooling assembly 203, 403A, 403B, 503 comprising the semiconductor device 204 and the manifold 206, 406, 506 from the bonded first and second substrates.

Singulation after bonding imparts distinctive structural characteristics on the integrated cooling assemblies 203, 403A, 403B, 503 as the bonding surface of each manifold 206, 406, 506 has the same perimeter as the backside of the semiconductor device 204, 501 bonded thereto. Thus, the sidewalls of the manifolds 206, 406, 506 are typically flush with the edges of the semiconductor device 204, 501 about their common perimeters. In some embodiments, the manifolds 206, 406, 506 are singulated from the first and second substrates using a process that cuts or divides the first and second substrate in a vertical plane (i.e., parallel to the Z-direction). In those embodiments, the sides of the manifold 206, 406, 506 are substantially perpendicular to the backside of the semiconductor device 204, 501 (i.e., a horizontal (X-Y) plane of an attachment interface between the semiconductor device 204, 501 and the manifolds 206, 406, 506). In some embodiments, the manifolds 206, 406, 506 are singulated using a saw or laser dicing process.

At block 630, the method 600 comprises sealingly attaching a package cover 208 to the integrated cooling assembly by use of a material layer disposed therebetween, where the package cover 208 comprising an inlet opening 214 and an outlet opening 213.

At block 640, the method 600 comprises before or after attaching the package cover 208 to the integrated cooling assembly 203, forming 640 openings in the material layer to fluidly connect the inlet opening 214 and the outlet opening 213 to the manifold 206, 406, 506.

It is contemplated that the methods above are not limited to crystalline silicon as sloped surfaces can be formed using other methods known to those skilled in the art. Thus, in some embodiments, the manifolds may be formed of a bulk material having a substantially similar coefficient of linear thermal expansion (CTE) to the bulk material of the device, where the CTE is a fractional change in length of the material (in the X-Y plane) per degree of temperature change. In some embodiments, the CTEs of the first and second substrates are matched so that the CTE of the second substrate is within about +/−20% or less of the CTE of the first substrate, such as within +/−15% or less, within +/−10% or less, or within about +/−5% or less when measured across a desired temperature range. In some embodiments, the CTEs are matched across a temperature range from about −60° C. to about 100° C. or from about 60° C. to about 175° C. In one example embodiment, the matched CTE materials each include silicon.

The method described above advantageously provides for integrated cooling assemblies that increased convective heat transfer from a semiconductor device to a coolant fluid, which facilitates an increase in power density of advanced device packages.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure. Only the claims that follow are meant to set bounds as to what the present disclosure includes.

1. A device package comprising:
an integrated cooling assembly comprising a semiconductor device and a manifold attached to the semiconductor device, wherein:
the manifold comprises:
a top portion;
a spacer extending downwardly from the top portion to a backside of the semiconductor device; and
a vibrational membrane disposed between portions of the manifold; and
the top portion, the spacer, and the backside of the semiconductor device collectively define a coolant chamber volume therebetween.

2. The device package of claim 1, wherein:
the manifold further comprises an inlet opening and an outlet opening; and
the coolant chamber volume is in fluid communication with the inlet opening and the outlet opening.

3. The device package of claim 1, wherein the vibrational membrane comprises one or more openings.

4. The device package of claim 2, wherein:
a portion of the vibrational membrane is spaced apart from the top portion of the manifold to define a fluid cavity; and
the coolant chamber volume is in fluid communication with the inlet openings through the fluid cavity and one or more openings of the vibrational membrane.

5. The device package of claim 3, wherein:
the vibrational membrane comprises a first surface facing the backside of the semiconductor device and a second surface opposite the first surface;
the one or more openings of the vibrational membrane are conduits; and
each conduit is defined by:
a first opening in the first surface;
a second opening in the second surface; and
a sidewall extending between the first and second openings.

6. The device package of claim 5, wherein a cross-sectional width of the second opening is greater than a cross-sectional width of the first opening.

7. The device package of claim 3, wherein sidewalls that define the one or more of the openings of the vibrational membrane comprise helicoid ribs.

8. (canceled)

9. The device package of claim 1, wherein the manifold is attached to the backside of the semiconductor device with direct bonding.

10. The device package of claim 1, wherein the manifold is attached to the backside of the semiconductor device with hybrid direct bonding.

11. The device package of claim 1, wherein the manifold is attached to the backside of the semiconductor device with a compliant adhesive layer.

12. The device package of claim 1, wherein the manifold is attached to the backside of the semiconductor device with solder.

13. The device package of claim 1, wherein the manifold is attached to the backside of the semiconductor device with eutectic bonding.

14. The device package of claim 1, wherein the vibrational membrane is configured to vibrate at a frequency from about 20 kHz to about 2 MHz.

15. The device package of claim 1, wherein the vibrational membrane comprises an actuator that generates sonic vibrations.

16. The device package of claim 1, wherein the vibrational membrane is configured to direct compressed streams of gas towards the backside of the semiconductor device.

17. The device package of claim 1, further comprising a package substrate, wherein:
the manifold is disposed on the package substrate, and
the semiconductor device is attached to the package substrate.

18. The device package of claim 1, wherein the manifold further comprises:
a package cover, the package cover having an inlet opening and an outlet opening disposed therethrough, and wherein:
the coolant chamber volume is in fluid communication with the inlet opening and the outlet opening of the package cover.

19. A device package comprising:
an integrated cooling assembly comprising a semiconductor device and a manifold attached to the semiconductor device, wherein:
the manifold comprises:
a top portion;
a spacer extending downwardly from the top portion to a bottom portion of the manifold; and
a vibrational membrane disposed between portions of the manifold; and
the top portion, the spacer, and the bottom portion collectively define a coolant chamber volume therebetween.

20-36. (canceled)

37. A method of manufacturing a device package, the method comprising:
directly bonding a first substrate comprising the manifold of claim 1 to a second substrate comprising a semiconductor device; and
singulating an integrated cooling assembly comprising the semiconductor device and the manifold from the bonded first and second substrates.

38. The method of claim 37, further comprising:
sealingly attaching a package cover to the integrated cooling assembly by use of a material layer disposed therebetween, the package cover comprising an inlet opening and an outlet opening; and
before or after attaching the package cover to the integrated cooling assembly, forming openings in the material layer to fluidly connect the inlet opening and the outlet opening to the manifold.
